(19) United States
(12) Patent Application Publication
(10) Pub. No.: US 2019/0115246 A1
(43) Pub. Date: Apr. 18, 2019

(54) METHODS AND APPARATUS FOR SHIELDING SUBSTRATE SUPPORTS

(71) Applicant: APPLIED MATERIALS, INC., Santa Clara, CA (US)

(72) Inventors: Kartik RAMASWAMY, San Jose, CA (US); Kenneth S. COLLINS, San Jose, CA (US); Michael R. RICE, Pleasanton, CA (US); James David CARDUCCI, Sunnyvale, CA (US)

(21) Appl. No.: 15/843,697

(22) Filed: Dec. 15, 2017

Related U.S. Application Data
(60) Provisional application No. 62/572,843, filed on Oct. 16, 2017.

(51) Int. Cl. H01L 21/687; H01L 21/67; H01J 37/32

(52) U.S. Cl. CPC H01L 21/68735; H01L 21/67069; H01J 37/32715; H01J 37/32633; H01J 2237/332; H01J 37/32568; H01J 2237/0262; H01J 2237/334; H01J 37/32183

(57) ABSTRACT

Apparatus for shielding a substrate support in a semiconductor processing chamber. In some embodiments, the apparatus includes: a substrate support body with a substrate processing surface, a feedthrough assembly for supporting the substrate support body in the semiconductor processing chamber, and a conductive member that provides a conductive path from a lowermost portion of the feedthrough assembly to the substrate processing surface of the substrate support body. The conductive member is disposed symmetrically about the substrate support.

### CROSS-REFERENCE TO RELATED APPLICATIONS

This application claims the benefit of U.S. provisional patent application Ser. No. 62/572,843, filed Oct. 16, 2017, which is herein incorporated by reference in its entirety.

### FIELD

Embodiments of the present principles generally relate to semiconductor processes.

### BACKGROUND

A semiconductor processing chamber used for deposition or etching typically has a substrate support with electrodes for assisting in the various processes. The electrodes can provide static charges for an electrostatic chuck to hold the substrate to the substrate support, power to heat the substrate, and power to facilitate in forming plasma over the substrate. In order for the semiconductor processes to create a uniform effect on the substrate, the electrodes should also perform in a uniform manner. The processing chamber, however, can be a hostile environment to electrical currents in the electrodes during processes such as plasma deposition. Electromagnetic waves, asymmetries in ground return paths in the chamber, and parasitic plasma formation can all effect the uniformity of the substrate processing.

Thus, the inventors have provided improved methods of shielding a substrate support during semiconductor processing.

### SUMMARY

Apparatus for shielding a substrate support in a semiconductor processing chamber are provided herein. In some embodiments, an apparatus for shielding a substrate support in a semiconductor processing chamber comprises a substrate support body with a substrate processing surface; a feedthrough assembly for supporting the substrate support body in the semiconductor processing chamber; and a substrate support conductive member that provides a conductive path from a lowermost portion of the feedthrough assembly to the substrate processing surface of the substrate support body, wherein the substrate support conductive member is disposed symmetrically about the substrate support.

In some embodiments, the substrate support conductive member includes a molybdenum-based material; the substrate support conductive member is disposed on a surface of the substrate support; or the substrate support conductive member is embedded beneath a surface of the substrate support.

In some embodiments the apparatus can further comprise a baffle ring surrounding the substrate support body and ohmically connected to the substrate support conductive member or an RF (Radio Frequency) conductive member embedded into the substrate support body and an RF power source electrically connected to the RF conductive member to supply RF power to the RF conductive member and electrically connected to the substrate support conductive member to receive returning RF power or an RF matching network interposed between the RF conductive member and the RF power source and between the substrate support conductive member and the RF power source or an RF conductive member embedded into the substrate support body and electrically connected to the substrate support conductive member and to DC ground to provide an RF return path for an RF powered electrode at a top of the semiconductor processing chamber or a variable impedance interposed between the RF conductive member and the substrate support conductive member and DC ground to control RF return current from returning via walls of the semiconductor processing chamber and from returning via the RF conductive member and the substrate support conductive member or a first RF power source at a top of the semiconductor processing chamber that provides RF current to an RF electrode to generate plasma and a second RF power source at a bottom of the semiconductor processing chamber that provides RF current to the substrate support conductive member and an RF conductive member embedded in the substrate support body to generate plasma or an RF matching network interposed between the first RF power source and the RF electrode or an RF matching network interposed between the second RF power source and the substrate support conductive member and the RF conductive member. In some embodiments, the substrate support conductive member partially surrounds the substrate support body or the substrate support conductive member partially surrounds the feedthrough assembly.

In some embodiments, an apparatus for shielding a substrate support in a semiconductor processing chamber comprises a conductive member symmetrically arranged around a substrate support body of the substrate support, wherein contact between the conductive member and the substrate support body is void of air gaps and wherein the conductive member provides an RF return path for plasma generation. In some embodiments, the conductive member is embedded below a surface of the substrate support body or the conductive member partially covers the substrate support body or the conductive member is symmetrically arranged around a feedthrough assembly of the substrate support, wherein contact between the conductive member and the feedthrough assembly is void of air gaps and wherein the conductive member provides and RF return path for plasma generation or the conductive member partially covers the feedthrough assembly.

In some embodiments, system for generating plasma in a semiconductor processing chamber comprises a substrate support with a substrate support body and a feedthrough assembly; a baffle ring that is conductive and surrounds the substrate support body; at least one RF electrode at a top of the semiconductor processing chamber opposite of a support surface of the substrate support body or embedded in the substrate support body parallel to the supporting surface of the substrate support body; and a conductive member arranged around the substrate support, wherein contact between the conductive member and the substrate support is void of air gaps and wherein the conductive member provides a symmetrical RF return path for the at least one RF electrode.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is an apparatus for shielding a substrate support in a processing chamber in accordance with some embodiments of the present principles.

FIG. 2 is an apparatus for shielding a substrate support in a processing chamber in accordance with some embodiments of the present principles.

FIG. 3 is an apparatus for shielding a substrate support in a processing chamber in accordance with some embodiments of the present principles.

FIG. 4 is an apparatus for shielding a substrate support in a processing chamber in accordance with some embodiments of the present principles.

FIG. 5 is an apparatus for shielding a substrate support in a processing chamber in accordance with some embodiments of the present principles.

FIG. 6 is an apparatus for shielding a substrate support in a processing chamber in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

A ceramic heater is a component of a semiconductor processing chamber that uses high temperatures for deposition of thin films or removal of thin films (etching). Oftentimes, the ceramic heater also includes an embedded Radio Frequency (RF) powered electrode that is used to generate plasma actively or passively by being a part of an RF receiving circuit (where an RF actively powered electrode is above a substrate or elsewhere in a semiconductor processing chamber). The arrangement makes the ceramic heater vulnerable to parasitic plasma as RF current travels to and from the embedded RF electrode in an unshielded environment.

Moreover, the RF current is forced to take long circuitous paths with large inductances, making the RF current return unrepeatable. The long RF current inductive paths make a semiconductor processing system vulnerable to system noise. Some embodiments of the present principles advantageously provide a low inductive RF current return path and also provide an electrostatic and/or electromagnetic shield at the same time. The low inductive RF current return path and shielding is accomplished by incorporating a conductive electrode that may surround heaters, RF electrodes, and/or chucking electrodes in a substrate support. The conductive electrode makes the RF current return repeatable and symmetric. The well-defined path of the RF current return advantageously eliminates noise problems associated with electromagnetic interference caused by long inductive paths.

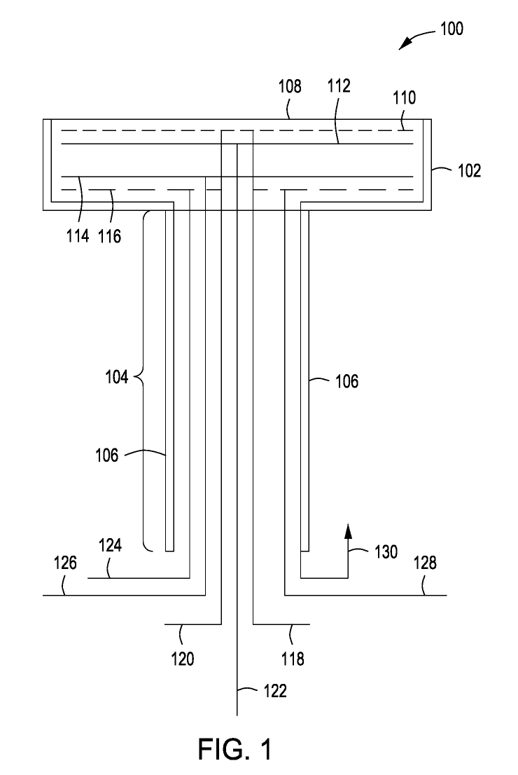

FIG. 1 is an apparatus for shielding a substrate support 100 in a semiconductor processing chamber in accordance with some embodiments. The substrate support 100 includes a substrate support body 102 which is supported by a feedthrough assembly 104. The feedthrough assembly 104 may also include a feedthrough shield 106 which is comprised of a conductive material such as aluminum. The feedthrough shield 106 generally functions as a heat shield and may be exposed to the semiconductor processing chamber environment (susceptible to process gases, high temperatures, and the like). The substrate support body 102 has a substrate processing surface 108 that would support a substrate (not shown) during processing. The substrate support body 102 may include, for example, a first conductive member 110 for supplying a static charge to hold a substrate to the substrate processing surface 108 (electrostatic chuck applications, generally supplied with DC+ and DC− charges to hold a substrate during processing). The first conductive member 110 may receive, for example, DC positive power from a first conductive electrode 118. The first conductive member 110 may receive, for example, DC negative power from a second conductive electrode 120.

The substrate support body 102 may include a second conductive member 112 that receives RF current and/or RF return current via, for example, a third conductive electrode 122 to facilitate in plasma generation within a semiconductor chamber. The substrate support body 102 may include a third conductive member 114 that receives AC current from, for example, a fourth conductive electrode 126 to heat a substrate on the substrate processing surface 108. The substrate support body 102 may include a fourth conductive member 116 that receives various AC current from, for example, a fifth conductive electrode 124 and a sixth conductive electrode 128 to provide additional heat to a substrate on the substrate processing surface 108 in various different heating zones (the fifth conductive electrode 124 and the sixth conductive electrode 128 can provide different levels of power and at different times).

In some embodiments as shown in FIG. 1, a substrate support conductive member 130 extends from a lower region of the feedthrough assembly 104 behind the feedthrough shield 106 and upwards embedded in the substrate support body 102 up to or near the substrate processing surface 108. The substrate support conductive member 130 may be affixed to a surface and/or embedded into the substrate support 100 such that no air gap occurs between the substrate support conductive member 130 and the substrate support body 102, the conductive members 110-116, and/or conductive electrodes 118-128. The lack of air gaps eliminates parasitic plasma generation. In some embodiments, the substrate support conductive member 130 may be a conductive shell affixed to a surface that encompasses a substantial portion of the feedthrough assembly 104 and the substrate support body 102. In some embodiments, the substrate support conductive member 130 may be an embedded conductive shell that encompasses a substantial portion of the feedthrough assembly 104 and the substrate support body 102.

In some embodiments, the substrate support conductive member 130 may partially encompass the feedthrough assembly 104 and substantially encompass the substrate support body 102. In some embodiments, the substrate support conductive member 130 may partially encompass the feedthrough assembly 104 and the substrate support body 102. In some embodiments, the substrate support conductive member 130 may be affixed to at least a portion of a surface of the substrate support 100. In some embodiments, the substrate support conductive member 130 may be embedded below a surface of the substrate support 100 to further protect the substrate support conductive member 130 from a processing environment of the semiconductor processing chamber. In some embodiments, the substrate support conductive member 130 may be a molybdenum-based material. In some embodiments, the substrate support conductive member 130 may be a semiconductive or conductive material that may withstand temperatures up to approximately 600 degrees Celsius or more. In some embodiments, the substrate support conductive member 130 may be symmetrical about the substrate support 100.

In some embodiments as shown in FIG. 1, the substrate support conductive member 130 operates as a ground that surrounds the electrodes in the feedthrough assembly 104. The substrate support conductive member 130 may act as an electrostatic shield against extraneous voltages. Because the substrate support conductive member 130 is advantageously affixed to a surface of and/or embedded in the substrate support 100, no air gap occurs between the substrate support conductive member 103 and any part of the substrate support 100, eliminating parasitic discharge.

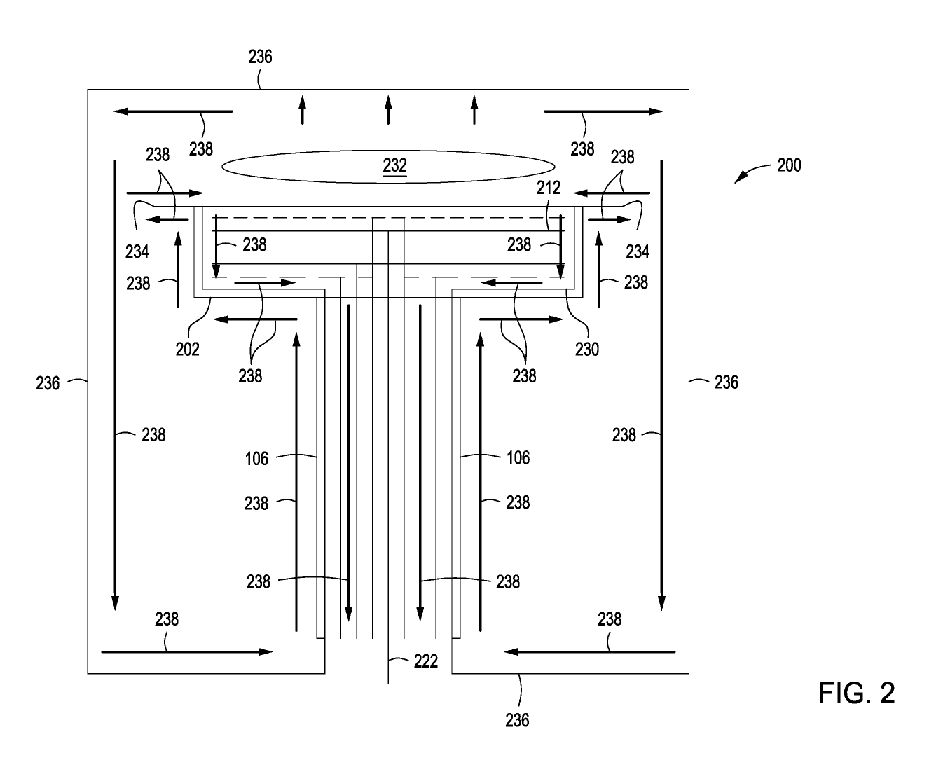

In some embodiments as shown in FIG. 2 where a second conductive member 212 supplied by a third conductive electrode 222 of a substrate support 200 is used to generate a plasma 232 above the substrate support 200. A substrate support conductive member 230 may be connected to an optional conductive baffle ring 234. The optional conductive baffle ring 234 may surround a substrate support body 202 and may be ohmically connected to the substrate support conductive member 230. The optional conductive baffle ring 234 and the substrate support conductive member 230 provide a symmetrical ground return path for RF currents generating the plasma 232. The substrate support conductive member 230 may be ohmically connected to walls 236 of a semiconductor processing chamber. In FIG. 2, the walls 236 of the semiconductor processing chamber provide part of an RF return path 238. The RF return path 238 progressives from the top of the semiconductor processing chamber and down through the walls 236 to the substrate support conductive member 230. The RF return path 238 then continues up through the substrate support conductive member 230, through the optional conductive baffle ring 234 and down through other electrodes in the substrate support 200 and back to an RF power source (not shown).

In some embodiments, the substrate support conductive member 230 provides electromagnetic shielding with cancellation of magnetic fields due to the opposite paths of the RF primary and return currents. In some embodiments, the elimination of an air gap between the substrate support conductive member 230 and the substrate support 200, conductive members, and/or conductive electrodes provides a superior voltage stand-off performance accompanied by a lack of parasitic plasma.

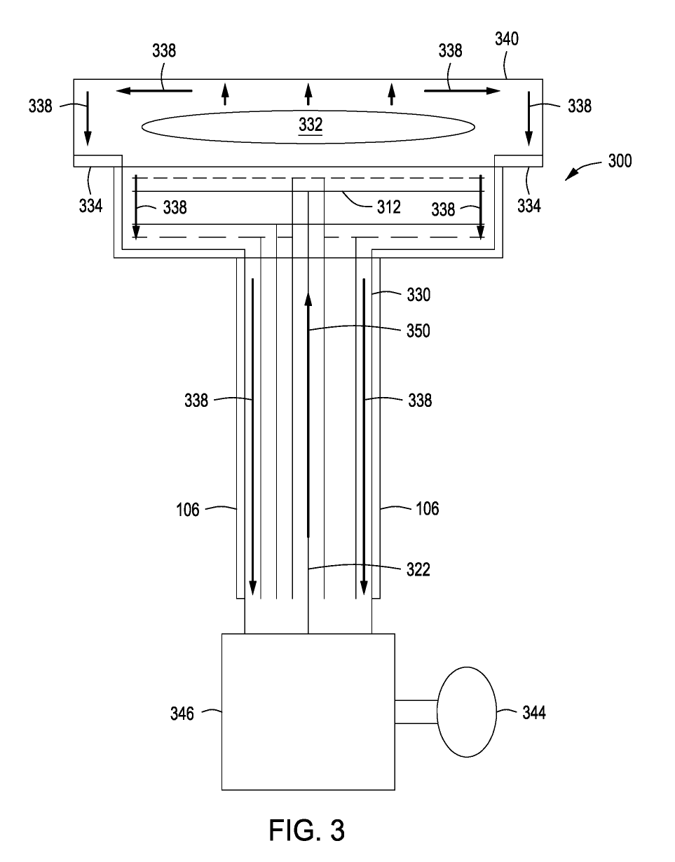

In some embodiments illustrated in FIG. 3, an optional conductive baffle ring 334 is connected to a top 340 of a semiconductor processing chamber allowing better confinement of a plasma 332 with a low inductance RF return current 338. The plasma 332 is generated by an RF power source 344 with an RF matching circuit 346 that provides RF power 350 to a second conductive member 312 via a third conductive electrode 322. The low inductance RF return current 338 symmetrically returns along an inside surface of a substrate support conductive member 330 to an RF power source 344 via an RF matching circuit 346.

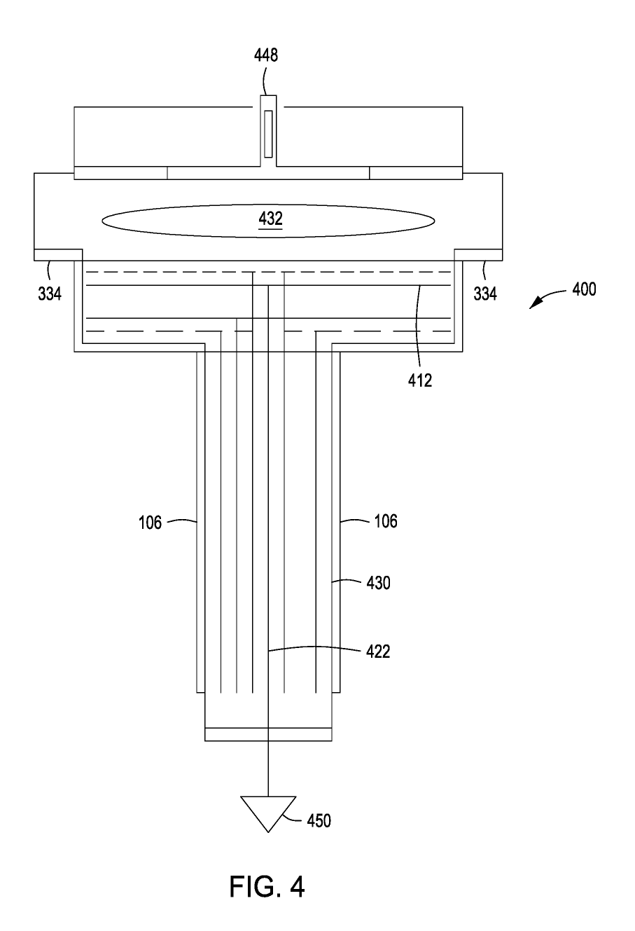

In some embodiments depicted in FIG. 4, a second conductive member 412 is electrically connected to a substrate support conductive member 430 via a third conductive electrode 422. An actively driven RF power electrode 448 is on the top of a semiconductor processing chamber to generate plasma 432 above the substrate support 400. The third conductive electrode 422 and the substrate support conductive member 430 are at a DC ground potential 450. The substrate support conductive member 430 provides a well-defined path for an RF return current with no air gap and no opportunity for parasitic plasma.

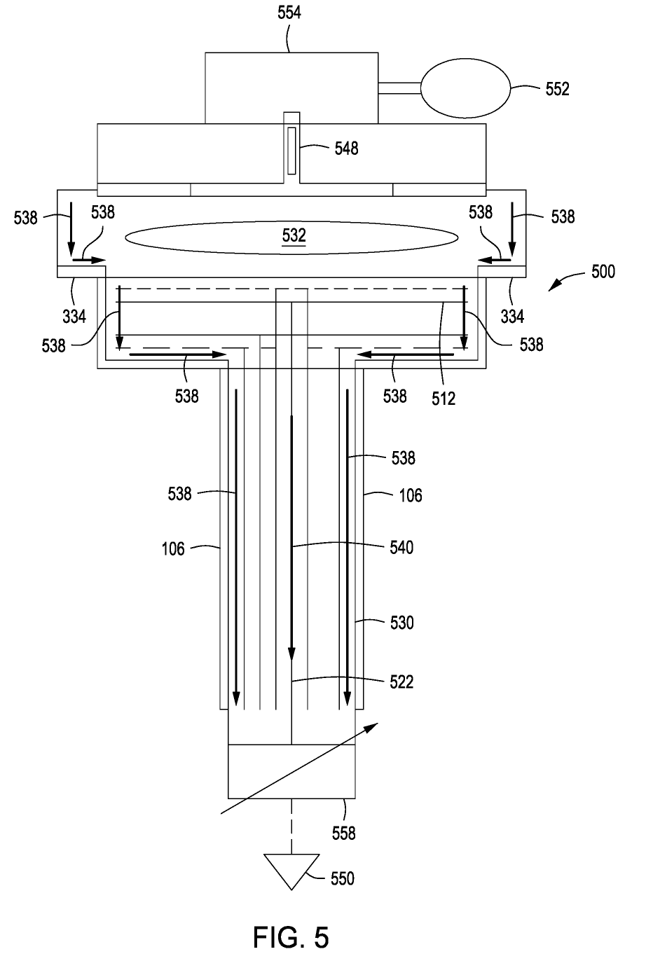

In some embodiments shown in FIG. 5, a second conductive member 512 is connected via a third conductive electrode 522 to a substrate support conductive member 530 through a variable impedance 558. The variable impedance 558 may vary impedance of the second conductive member 512 and/or the substrate support conductive member to an optional DC ground 550 during generation of plasma 532. The variable impedance 558 controls a first RF return current 540 returning via the substrate support 500 against a second RF return current 538 returning through walls of a semiconductor processing chamber directly. The RF current originates from an RF power source 552 that provides RF power via an RF matching network 554 to an RF electrode 548 at a top of the semiconductor processing chamber.

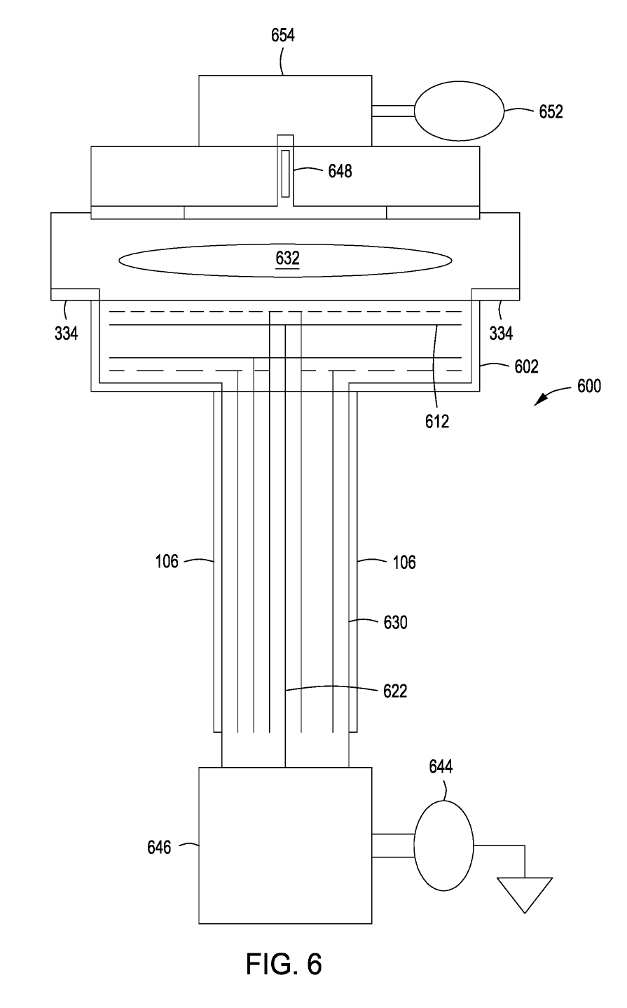

In some embodiments shown in FIG. 6, a semiconductor processing chamber has a first RF power source 652 and a second RF power source 644 to generate plasma 632. The first RF power source 652 connects to an RF power electrode 648 via a first RF matching network 654. The second RF power source 644 connects via a second RF matching network 646 to a second conductive member 612 via a third conductive electrode 622 and connects to a substrate support conductive member 630. The substrate support conductive member 630 carries a well-defined RF return current, providing electrostatic and electromagnetic shielding. Parasitic discharge is also eliminated because no air gap exists between the substrate support conductive member 630 and a substrate support body 602 of the substrate support 600.

While the foregoing is directed to embodiments of the present principles, other and further embodiments of the principles may be devised without departing from the basic scope thereof.

1. An apparatus for shielding a substrate support in a semiconductor processing chamber, comprising:
a substrate support body with a substrate processing surface;
a feedthrough assembly for supporting the substrate support body in the semiconductor processing chamber; and
a substrate support conductive member that provides a conductive path from a lowermost portion of the feedthrough assembly to the substrate processing surface of the substrate support body, wherein the substrate support conductive member is disposed symmetrically about the substrate support.

2. The apparatus of claim 1, wherein the substrate support conductive member comprises a molybdenum-based material.

3. The apparatus of claim 1, wherein the substrate support conductive member is disposed on a surface of the substrate support.

4. The apparatus of claim 1, wherein the substrate support conductive member is embedded beneath a surface of the substrate support.

5. The apparatus of claim 1, further comprising:
a baffle ring surrounding the substrate support body and ohmically connected to the substrate support conductive member.

6. The apparatus of claim 5, further comprising:
an RF conductive member embedded into the substrate support body; and
an RF power source electrically connected to the RF conductive member to supply RF power to the RF conductive member and electrically connected to the substrate support conductive member to receive returning RF power.

7. The apparatus of claim 6, further comprising:
an RF matching network interposed between the RF conductive member and the RF power source and between the substrate support conductive member and the RF power source.

8. The apparatus of claim 5, further comprising:
an RF conductive member embedded into the substrate support body and electrically connected to the substrate support conductive member and to DC ground to provide an RF return path for an RF powered electrode at a top of the semiconductor processing chamber.

9. The apparatus of claim 8, further comprising:
a variable impedance interposed between the RF conductive member and the substrate support conductive member and DC ground to control RF return current from returning via walls of the semiconductor processing chamber and from returning via the RF conductive member and the substrate support conductive member.

10. The apparatus of claim 5, further comprising:
a first RF power source at a top of the semiconductor processing chamber that provides RF current to an RF electrode to generate plasma; and
a second RF power source at a bottom of the semiconductor processing chamber that provides RF current to the substrate support conductive member and an RF conductive member embedded in the substrate support body to generate plasma.

11. The apparatus of claim 10, further comprising:
an RF matching network interposed between the first RF power source and the RF electrode.

12. The apparatus of claim 10, further comprising:
an RF matching network interposed between the second RF power source and the substrate support conductive member and the RF conductive member.

13. The apparatus of claim 1, wherein the substrate support conductive member partially surrounds the substrate support body.

14. The apparatus of claim 1, wherein the substrate support conductive member partially surrounds the feedthrough assembly.

15. An apparatus for shielding a substrate support in a semiconductor processing chamber, comprising:
a conductive member symmetrically arranged around a substrate support body of the substrate support, wherein contact between the conductive member and the substrate support body is void of air gaps and wherein the conductive member provides an RF return path for plasma generation.

16. The apparatus of claim 15, wherein the conductive member is embedded below a surface of the substrate support body.

17. The apparatus of claim 15, wherein the conductive member partially covers the substrate support body.

18. The apparatus of claim 15, wherein the conductive member is symmetrically arranged around a feedthrough assembly of the substrate support, wherein contact between the conductive member and the feedthrough assembly is void of air gaps and wherein the conductive member provides and RF return path for plasma generation.

19. The apparatus of claim 18, wherein the conductive member partially covers the feedthrough assembly.

20. A system for generating plasma in a semiconductor processing chamber, comprising:
a substrate support with a substrate support body and a feedthrough assembly;
a baffle ring that is conductive and surrounds the substrate support body;
at least one RF electrode at a top of the semiconductor processing chamber opposite of a support surface of the substrate support body or embedded in the substrate support body parallel to the supporting surface of the substrate support body; and
a conductive member arranged around the substrate support, wherein contact between the conductive member and the substrate support is void of air gaps and wherein the conductive member provides a symmetrical RF return path for the at least one RF electrode.
